(19) United States
(12) Patent Application Publication
(10) Pub. No.: US 2025/0221148 A1
(43) Pub. Date: Jul. 3, 2025

(54) LIGHT EMITTING DEVICE AND LIGHT EMITTING DISPLAY DEVICE INCLUDING SAME

(71) Applicant: LG Display Co., Ltd., Seoul (KR)

(72) Inventors: Mi Na KIM, Paju-si (KR); Moon Sung KIL, Paju-si (KR)

(73) Assignee: LG Display Co., Ltd., Seoul (KR)

(21) Appl. No.: 18/926,185

(22) Filed: Oct. 24, 2024

(30) Foreign Application Priority Data
Dec. 29, 2023 (KR) 10-2023-0197863

(51) Int. Cl. H10K 50/12; H10K 50/18; H10K 101/30; H10K 101/40

(52) U.S. Cl. CPC H10K 50/12; H10K 50/181; H10K 2101/30; H10K 2101/40

(57) ABSTRACT

Discussed is a light emitting device, including a first electrode and a second electrode facing each other, an electron blocking layer, a first emission layer, and an electron transport layer between the first electrode and the second electrode. The first emission layer includes a first p-type host, a second p-type host, an n-type host, and a dopant. A HOMO energy level of the first p-type host is lower than a HOMO energy level of the second p-type host, and hole mobility of the second p-type host is greater than hole mobility of the first p-type host.

### CROSS-REFERENCE TO RELATED APPLICATIONS

This application claims priority to Korean Patent Application No. 10-2023-0197863, filed in the Republic of Korea on Dec. 29, 2023, the entire contents of which is hereby expressly incorporated by reference into the present application.

### BACKGROUND OF THE DISCLOSURE

### Field

The present disclosure relates to a light emitting device, and more particularly to a light emitting display device having improved luminous efficacy and lifespan.

### Discussion of the Related Art

With advent of a full-fledged information era at the present, a field of display technology that provides visually displays via electrical information signals has rapidly developed, and accordingly, a variety of display devices with excellent characteristics such as slimness, light weight, and low power consumption are being developed and improved upon.

Among such display devices, a light emitting display device configured to self-illuminate and obviate a need for a separate light source is becoming popular, and a light emitting device can be used in a display panel for its compactness and clear color display.

Such a light emitting device for the light emitting display device can include an anode and a cathode facing each other as electrodes, an emission layer between the anode and the cathode, and a common layer that transfers holes and electrons to the emission layer.

Further, emission materials that emit light at different wavelengths for color display can be used for the emission layer of the light emitting device, but there can occur differences in efficiency and lifespan depending on the type of the emission materials that are used for different color light.

### SUMMARY OF THE DISCLOSURE

An object of the present disclosure is to provide a light emitting device and a light emitting display device including the same, in which both efficiency and lifespan of the light emitting device can be improved by changing the material contained in an emission layer, and parasitic capacitance of an intermediate layer structure including the emission layer between first and second electrodes can be decreased and capacitance threshold voltage of the intermediate layer structure can be increased, improving reliability.

Another object of the present disclosure is to provide an improved light emitting device and an improved display device including the same, which address the limitations and disadvantages associated with the related art.

An embodiment of the present disclosure provides a light emitting device, in which an emission layer includes, as p-type hosts that control hole transport, a first p-type host with a low Highest Occupied Molecular Orbital (HOMO) energy level and a second p-type host with high hole mobility, and an n-type host with high electron mobility, making it possible to lower operating voltage, achieve long lifespan, and increase capacitance threshold voltage for device reliability.

The light emitting device according to an embodiment of the present disclosure can include a first electrode and a second electrode facing each other, and an electron blocking layer, a first emission layer, and an electron transport layer between the first electrode and the second electrode, in which the first emission layer can include a first p-type host, a second p-type host, an n-type host, and a dopant, the HOMO energy level of the first p-type host can be lower than the HOMO energy level of the second p-type host, and the hole mobility of the second p-type host can be greater than the hole mobility of the first p-type host.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a cross-sectional view showing a light emitting device according to an embodiment of the present disclosure;

FIG. 2 schematically shows a configuration of the emission layer of FIG. 1;

FIG. 3 shows an energy band diagram of compounds included in the emission layer of FIG. 1;

FIG. 4 shows an energy band diagram of a red emission layer and adjacent layers in a red light emitting device according to an embodiment of the present disclosure;

FIG. 5 is a graph comparing J-V characteristics of a first host and a second host using HODs (hole only devices);

FIG. 6 is a graph showing J-V characteristics of the first to fifth experimental examples;

FIG. 7 is a graph showing lifespan of the first to fifth experimental examples;

FIG. 8 is a graph showing C-V characteristics of the first to fifth experimental examples;

FIG. 9 is a cross-sectional view showing a light emitting device according to an embodiment of the present disclosure; and

FIG. 10 is a cross-sectional view showing a light emitting display device according to an embodiment of the present disclosure.

### DETAILED DESCRIPTION OF THE EMBODIMENTS

Reference will now be made in detail to example embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations maybe omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

In the following description of the present disclosure, the Lowest Unoccupied Molecular Orbital (LUMO) energy level and the Highest Occupied Molecular Orbital (HOMO) energy level of a layer mean the LUMO energy level and the HOMO energy level of a material constituting a major weight ratio of the corresponding layer, unless they refer to the LUMO energy level and the HOMO energy level of a dopant material doping the corresponding layer.

In the following description of the present disclosure, a HOMO energy level can be obtained by measuring a voltage corresponding to a first peak at which electrons are emitted from a material through cyclic voltammetry (CV) for the material to be measured, compared to a reference material whose HOMO energy level is known. Herein, the electron that first comes out of the material is the weakest bound electron, e.g., the outermost electron, and is in the state of the HOMO energy level. As an example, the HOMO energy levels and the LUMO energy levels in the Tables of present disclosure, are compared to a HOMO energy level and a LUMO energy level of NPD (N,N′-Di(1-naphthyl)-N,N′-diphenyl-(1,1′-biphenyl)-4,4′-diamine). NPD has a HOMO energy level −5.5 eV and a LUMO energy level of −2.4 eV. But embodiments of the present disclosure are not limited thereto.

In the present disclosure, a band gap energy (Eg) can be measured by ultraviolet-visible spectrometry (UVvis).

In the present disclosure, a LUMO energy level can be obtained by subtracting the band gap energy from the HOMO energy level measured above.

In the present disclosure, the HOMO energy level and the LUMO energy level are measured values below the vacuum level of 0 eV, thus they are negative values. When the HOMO energy levels or LUMO energy levels of materials are compared, that the HOMO energy level (or the LUMO energy level) of a first material is larger than the HOMO energy level (or the LUMO energy level) of a second material in an energy band diagram means that the HOMO energy level (or the LUMO energy level) of the second material is larger than the HOMO energy level (or the LUMO energy level) of the first material in absolute values. When the HOMO energy levels or LUMO energy levels of materials are compared, that the HOMO energy level (or the LUMO energy level) of a first material is lower than the HOMO energy level (or the LUMO energy level) of a second material in an energy band diagram means that the HOMO energy level (or the LUMO energy level) of the first material is larger than the HOMO energy level (or the LUMO energy level) of the second material in an absolute value.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. Further, for convenience of description, a scale in which each of elements is illustrated in the accompanying drawings can differ from an actual scale. Thus, the illustrated elements are not limited to the specific scale in which they are illustrated in the drawings.

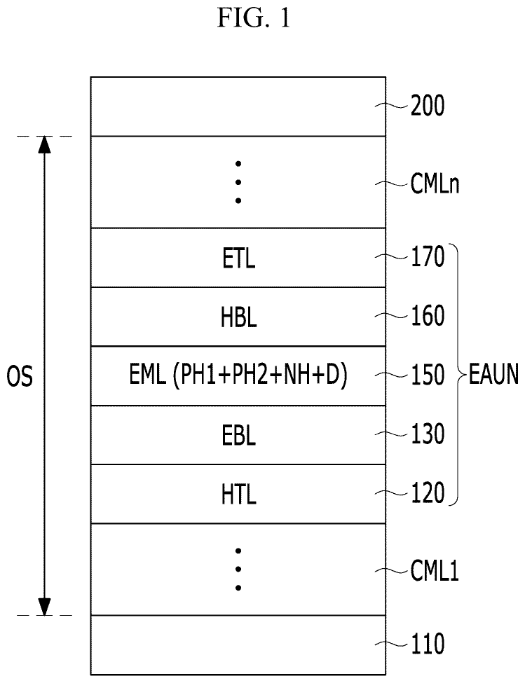

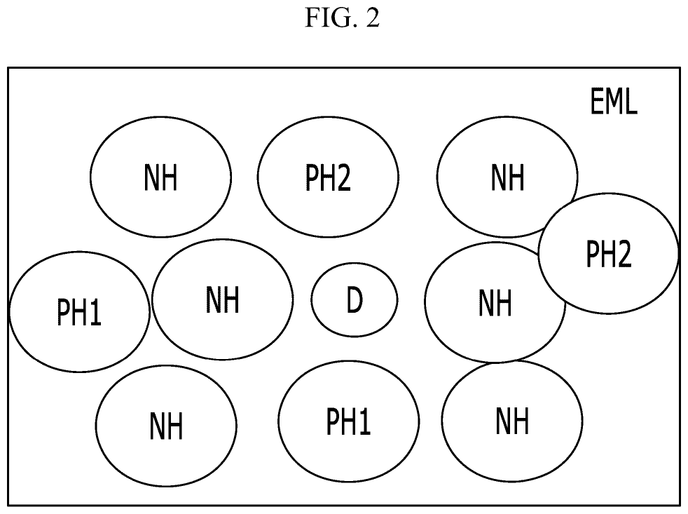

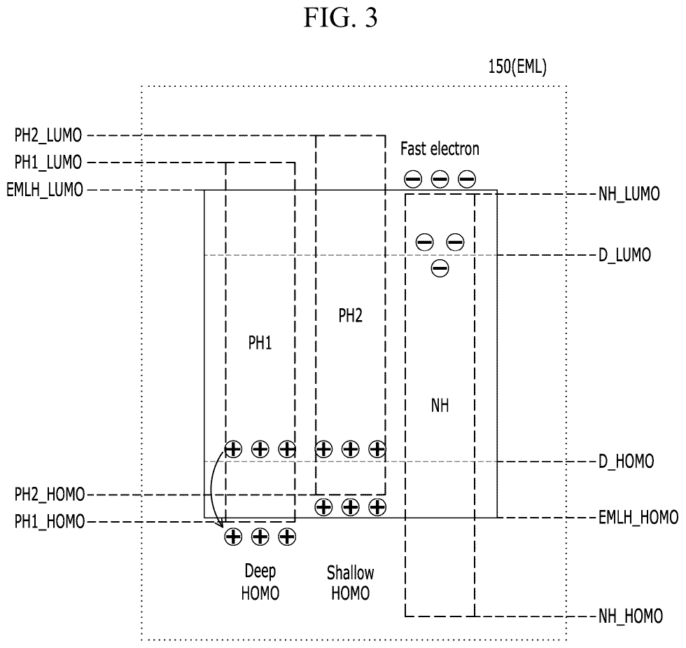

FIG. 1 is a cross-sectional view showing a light emitting device according to an embodiment of the present disclosure, and FIG. 2 schematically shows the configuration of the emission layer of FIG. 1. FIG. 3 shows an energy band diagram of the compounds included in the emission layer of FIG. 1. All the components of each light emitting device and each display device including the same according to all embodiments are operationally coupled and configured.

As shown in FIG. 1, the light emitting device according to an embodiment of the present disclosure includes a first electrode 110 and a second electrode 200 facing each other, and an intermediate layer structure OS provided between the first electrode 110 and the second electrode 200. But embodiments of the present disclosure are not limited thereto, and additional elements or structures can be used in the light emitting device.

Any one of the first electrode 110 and the second electrode 200 can be an anode and the remaining one can be a cathode. FIG. 1 shows an example in which the first electrode 110 is an anode and the second electrode 200 is a cathode, but the embodiment of the present disclosure is not limited thereto.

Any one of the first electrode 110 and the second electrodes 200 can be connected to the thin film transistor of each sub-pixel provided on a substrate, and the remaining one can receive a common voltage from a plurality of sub-pixels.

Any one of the first electrode 110 and the second electrode 200 can be a reflective electrode, and the remaining one can be a transparent electrode or a semi-transparent electrode. When the first electrode 110 is a reflective electrode and the second electrode 200 is a transparent electrode or a semi-transparent electrode, a top-emission light emitting device can be realized. When the first electrode 110 is a transparent electrode and the second electrode 200 is a reflective electrode, a bottom-emission light emitting device can be realized. In an embodiment of the present disclosure, when each of the first electrode 110 and the second electrode 200 is a non-reflective electrode, a dual-emission light emitting device can be realized. When the first electrode 110 is a reflective electrode, the reflective electrode can include a plurality of layers. For example, the reflective electrode can include a layered structure of ITO/Ag or an Ag alloy layer/ITO, or Ag or an Ag alloy layer/ITO. But embodiments of the present disclosure are not limited thereto.

The first electrode 110 can be connected to the thin film transistor provided on the substrate to selectively receive a signal supplied to each sub-pixel, and the second electrode 200 can be provided in common to the sub-pixels to receive a common voltage. By inverting the device configuration of FIG. 1 upside down, the second electrode 200 located at the lower side can be connected to a thin film transistor, and the first electrode 110 located at the upper side can be provided across a plurality of sub-pixels to receive a common voltage.

The intermediate layer structure OS can be provided between the first and second electrodes 110, 200, and emission characteristics of the light emitting device can be controlled depending on the thickness of the intermediate layer structure OS and the layers included in the intermediate layer structure OS. The intermediate layer structure OS can include a plurality of organic layers. Some of the layers included in the intermediate layer structure OS can further include a metal or an inorganic material other than the metal. The inorganic material other than the metal can be provided alone in some of the layers, or can form a complex with an organic material.

For example, the intermediate layer structure OS can include a first common layer CML1, a light emitting unit EAUN, and an n^{th} common layer CMLn.

The first common layer CML1 can be, for example, a hole injection layer HIL. The first common layer CML1 in contact with the first electrode 110 can be formed of a single organic or inorganic hole injection material, or can be formed by adding a p-type dopant to a hole transport material. The first common layer CML1 serves to reduce a barrier in supplying holes from the first electrode 110 to the intermediate layer structure 200.

The n^{th} common layer CMLn can be an electron injection layer EIL. The n^{th} common layer CMLn is disposed in contact with the second electrode 200 and serves to reduce a barrier in injecting electrons from the second electrode 200 to the intermediate layer structure OS. The electron injection layer EIL can include a halogen atom coupled with an alkali metal or alkaline earth metal or an electron transport organic material.

At least one of the first common layer CML1 or the n^{th} common layer CMLn can have a multilayer structure.

The light emitting unit EAUN includes a hole transport layer HTL 120, an electron blocking layer EBL 130, an emission layer EML 150, a hole blocking layer HBL 160, and an electron transport layer ETL 170. But embodiments of the present disclosure are not limited thereto.

The thickness or arrangement of at least one layer provided in the light emitting unit EAUN can be adjusted for each sub-pixel, and thus it can be distinguished from the first common layer CML1 and the n^{th} common layer CMLn described above.

For example, when red, green, and blue sub-pixels are provided on the substrate, the thickness of at least one layer selected from among a hole transport layer HTL 120, an electron blocking layer EBL 130, an emission layer EML 150, a hole blocking layer HBL 160, and an electron transport layer ETL 170 can be differently set for each sub-pixel, the material of at least one layer can be varied, or at least one layer can be omitted in a sub-pixel of a specific color. Thereby, the optical distance for each emission color can be adjusted.

In a structure in which an emission layer is different for each sub-pixel, the remaining layers except for the emission layer EML 150, namely the first common layer CML1, the hole transport layer HTL 120, the electron blocking layer EBL 130, the hole blocking layer HBL 160, the electron transport layer ETL 170, and the n^{th} common layer CMLn can be provided in common for each sub-pixel.

At least one layer selected from among the first common layer CML1, the hole transport layer HTL 120, the electron blocking layer EBL 130, the emission layer EML 150, the hole blocking layer HBL 160, the electron transport layer ETL 170, and the n^{th} common layer CMLn can have a multilayer structure and can be formed by changing the amount or type of any material in the multilayer structure.

In the light emitting unit EAUN of the present disclosure, the hole transport layer 120 and the electron blocking layer 130 disposed under the emission layer EML 150 are hole transport-related layers. The HOMO energy levels (HTL_HOMO, EBL_HOMO) of the hole transport layer 120 and the electron blocking layer 130 are lower than the HOMO energy level of the mixed host of the emission layer 150 so as to efficiently transfer, to the emission layer 150, the holes injected through the first common layer CML1 from the first electrode 110. The hole blocking layer 160 and the electron transport layer 170 disposed on the emission layer EML 150 are electron transport-related layers. In some cases, the hole blocking layer 160 can be omitted in embodiments of the present disclosure. When the hole blocking layer 160 is omitted, the emission layer 150 can be in direct contact with the electron transport layer 170.

The LUMO energy levels (HBL_LUMO, ETL_LUMO) of the hole blocking layer 160 and the electron transport layer 170 are higher than the LUMO energy level of the mixed host of the emission layer 150 so as to efficiently transfer, to the emission layer 150, the electrons injected through the n^{th} common layer CMLn from the second electrode 200.

As shown in FIGS. 1 to 3, the emission layer 150 includes a first p-type host PH1, a second p-type host PH2, an n-type host NH, and a dopant D. In the emission layer 150 according to an embodiment of the present disclosure, both the first and second p-type hosts PH1, PH2 have hole transport capability and thus differ from the n-type host NH having electron transport capability, and these have different properties as described below.

As shown in FIG. 3, the first p-type host PH1 has a low HOMO energy level and increases hole trapping efficiency from the adjacent electron blocking layer 130. The holes injected into the emission layer 150 move directly from the first p-type host PH1 to the HOMO energy level of the dopant D or are transferred again to the HOMO energy level of the dopant D through the HOMO energy level of the second p-type host PH2 with a smaller difference than the HOMO energy level of the dopant D, and the holes in the HOMO energy level of the dopant D recombine with the electrons transferred from the LUMO energy level of the n-type host NH to the LUMO energy of the dopant D to form excitons, which are used for light emission. Since the first p-type host PH1 induces the holes trapped in the low HOMO energy level to recombine with electrons transferred through the hole blocking layer 160 or the electron transport layer 170 with high mobility in the emission layer 150, charge trapping of the emission layer 150 can be increased. Specifically, the first p-type host PH1 causes recombination of holes and electrons forming excitons to occur mainly in the emission layer 150, rather than at the interface between the emission layer and the electron blocking layer 130, thus preventing charges such as excitons, etc. from leaking into the electron blocking layer 130, thereby making it possible to prevent a decrease in efficiency and a decrease in lifespan occurring when a light emitting region is intensively formed between the emission layer 150 and the electron blocking layer 130.

Further, enhanced charge trapping in the emission layer 150 by the first p-type host PH1 can increase the capacitance threshold voltage of the light emitting device.

The term “capacitance threshold voltage” refers to a reference voltage at which capacitance changes rapidly. In a C-V (capacitance-voltage) graph with voltage on the horizontal axis and capacitance on the vertical axis, the voltage value at the point where the curve occurs is called the capacitance threshold voltage.

The capacitance of the light emitting device is generated in the intermediate layer structure OS between the first electrode 110 and the second electrode 200. The capacitance of the intermediate layer structure OS is caused by the entire intermediate layer structure OS, but in the embodiment of the present disclosure, the capacitance threshold voltage of the intermediate layer structure OS is increased by changing the configuration of the emission layer 150, thus reducing or preventing a variation in capacitance between the first and second electrodes 110, 200, so that the characteristics of the light emitting device and the FOS (front of screen test) characteristics when implemented as a light emitting display device are stabilized.

Among the layers forming the intermediate layer structure OS, the emission layer 150 can include a different material for each sub-pixel emitting light of a different color, and the layers other than the emission layer 150 can be provided in common, and thus each sub-pixel can exhibit different capacitance or different capacitance threshold voltage depending mainly on the emission layer.

When the capacitance threshold voltage is low, even a small voltage applied between the first and second electrodes can significantly change the capacitance of the light emitting device, causing a change in characteristics. Therefore, the light emitting device according to an embodiment of the present disclosure includes the first p-type host PH1 capable of increasing charge trapping efficiency in the emission layer, increasing the capacitance threshold voltage.

The second p-type host PH2 is a material having a higher HOMO energy level than the first p-type host PH1 and higher hole mobility than the first p-type host PH1. The HOMO energy level of the second p-type host PH2 has a small energy difference from the HOMO energy level of the dopant D, facilitates hole transfer, and also has high hole mobility, thus maintaining high mobility balance with electrons by the n-type host NH in the emission layer and increasing hole-electron recombination efficiency, thereby reducing generation of charges that are not used for recombination. Therefore, the lifespan of the light emitting device can be improved by preventing charges that are not used for recombination from accumulating at the interface between the emission layer and the electron blocking layer.

In the light emitting device of the present disclosure, the emission layer can include the first and second p-type hosts PH1, PH2 and the n-type host NH, playing a role related to hole transfer in the emission layer, increasing luminous efficacy through charge trapping in the emission layer, obtaining low-voltage operating characteristics, increasing reliability of capacitance-voltage characteristics as the electrical characteristics of the light emitting device by increasing the capacitance threshold voltage of the light emitting device, and improving a long lifespan effect by preventing charges from being biased toward the adjacent electron blocking layer.

In the emission layer EML 150, the first p-type host PH1, the second p-type host PH2, and the n-type host NH are premixed and supplied as a host material Host from a single source during the deposition process, and are formed on the electron blocking layer 130 along with the dopant deposited from a different source. The first p-type host PH1, the second p-type host PH2, and the n-type host NH can be evenly distributed throughout the thickness of the emission layer EML 150.

The dopant D is contained in an amount of 0.1 wt % to 20 wt % based on the total amount of the hosts, and serves to adjust the wavelength of light emitted from the emission layer 150. But embodiments of the present disclosure are not limited thereto.

For example, when the dopant D is a red dopant or a green dopant, an iridium complex dopant can be used. When the dopant D emits red light, it can have an emission peak at a wavelength of 600 nm to 650 nm. When the dopant D emits green light, it can have an emission peak at a wavelength of 510 nm to 580 nm. But embodiments of the present disclosure are not limited thereto.

For example, the light emitting device according to an embodiment of the present disclosure can increase the effect of stabilizing C-V (capacitance-voltage) characteristics using the first and second p-type hosts PH1, PH2 as two hosts having different properties in a structure in which the dopant D is a red dopant. Here, the embodiment of the present disclosure is not limited to the use of the red dopant, but can also be applied to using dopants of other colors from the viewpoint of lowering operating voltage, increasing luminous efficacy, exhibiting a long lifespan effect, and stabilizing C-V characteristics.

The total amount of the first and second p-type hosts PH1, PH2 in the emission layer EML 150 can be equal to or very similar to the amount of the n-type host NH. This ensures that the balance between holes and electrons is maintained in a structure using a dopant with a small energy band gap (Eg). The red dopant has a smaller energy band gap than dopants of other visible light wavelengths.

When hosts are mixed and included in the emission layer EML, the emission layer EML thus formed has the HOMO energy level of the mixed host and the LUMO energy level of the mixed host from a barrier perspective with respect to adjacent layers. As such, in an embodiment of the present disclosure, the HOMO energy level (EMLH_HOMO) of the mixed host Host of the emission layer is not the average value of the HOMO energy levels of hosts, but is the closest to the HOMO energy level (PH1_HOMO) of the first p-type host PH1 having the relatively low HOMO energy level among p-type hosts with hole transport characteristics, as shown in FIG. 3. In addition, in an embodiment of the present disclosure, the LUMO energy level (EMLH_LUMO) of the mixed host Host of the emission layer is not the average value of the LUMO energy levels of hosts, but is the closest to the LUMO energy level (NH_LUMO) of the n-type host with electron transport characteristics, as shown in FIG. 3. This is because holes and electrons move in a direction with a low energy barrier.

In the emission layer EML 150, not only the first and second p-type hosts PH1, PH2 and the n-type host NH but also the dopant D are evenly distributed there throughout, thus generating excitons in the dopant distributed throughout the emission layer 150 by energy received from individual hosts, and light emission occurs accordingly.

Meanwhile, the first p-type host PH1 is a tertiary arylamine compound and can be represented by Chemical Formula 1 below.

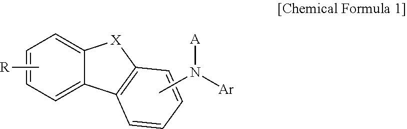

Here, X can be independently selected from among hydrogen, deuterium, substituted or unsubstituted C1-C20 alkyl, C3-C20 cycloalkyl, substituted or unsubstituted C6-C30 aryl, and substituted or unsubstituted C5-C30 heteroaryl. But embodiments of the present disclosure are not limited thereto.

Further, A and Ar can each be independently selected from among substituted or unsubstituted C6-C30 aryl and substituted or unsubstituted C5-C30 heteroaryl. Here, A and Ar can be the same as or different from each other.

Here, R can be hydrogen, deuterium, or substituted or unsubstituted aryl.

The second p-type host PH2 is a tertiary arylamine compound. In some cases, the second p-type host PH2 can use the same core as Chemical Formula 1, but by varying the component of the organic substituent that binds to nitrogen, the HOMO energy level can be adjusted and hole mobility can be designed quickly compared to the first p-type host PH1.

The n-type host NH can be a material with high electron mobility. For example, the n-type host NH can be a quinazoline derivative. The n-type host NH can include any one selected from among triazole, triazine, benzothiazole, carbazole, benzimidazole, and oxadiazole. But embodiments of the present disclosure are not limited thereto.

Below is a description of application of the light emitting device according to the present disclosure to a red sub-pixel.

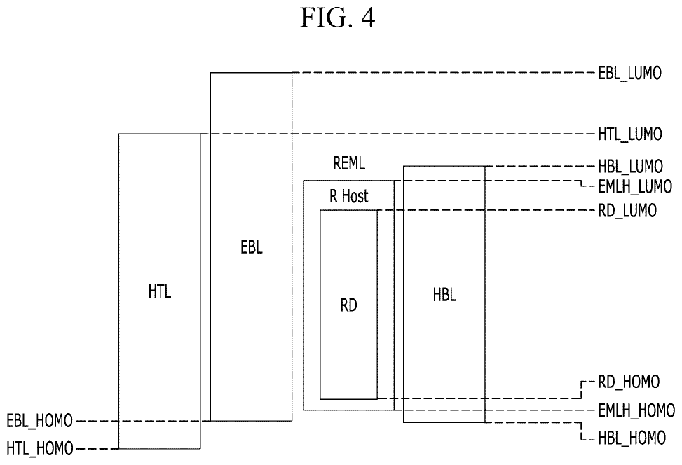

FIG. 4 shows an energy band diagram of a red emission layer and adjacent layers in a red light emitting device according to an embodiment of the present disclosure.

As shown in FIG. 4, from a hole transfer perspective, the HOMO energy levels (HTL_HOMO, EBL_HOMO, EMLH_HOMO, RD_HOMO) increase sequentially in the order of the hole transport layer HTL, the electron blocking layer EBL, the mixed host R Host of the red emission layer EML, and the red dopant RD. Briefly, there is a relationship of HTL_HOMO<EBL_HOMO<EMLH_HOMO<RD_HOMO.

The electron blocking layer is designed to have a LUMO energy level higher than the LUMO energy level of the mixed host R Host to prevent excitons or electrons from escaping from the red emission layer REML.

Further, from a transfer perspective, the LUMO energy levels (HBL_LUMO, EMLH_LUMO, RD_LUMO) sequentially decrease in the order of the hole blocking layer HBL, the mixed host R Host of the red emission layer EML, and the red dopant RD. Briefly, there is a relationship of HBL_LUMO>EMLH_LUMO>RD_LUMO.

The hole blocking layer HBL is designed to have a HOMO energy level lower than the HOMO energy level of the mixed host R Host to prevent holes from escaping from the red emission layer REML.

Meanwhile, the hole transport layer HTL can have a LUMO energy level (HTL_LUMO) higher than the LUMO energy level of the mixed host R Host (EMLH_LUMO) to further strengthen blocking of excitons or electrons. However, the embodiment of the present disclosure is not limited thereto.

When the hole blocking layer HBL is omitted, the red emission layer REML can be in direct contact with the electron transport layer ETL. Here, the energy band gap (Eg) of the electron transport layer ETL is set to have a LUMO energy level higher than the LUMO energy level of the mixed host R Host and a HOMO energy level lower than the HOMO energy level thereof.

The HOMO energy level (EMLH_HOMO) of the mixed host R Host of the red emission layer REML can be lower than the HOMO energy level (RD_HOMO) of the red dopant RD (EMLH_HOMO<RD_HOMO), and the LUMO energy level (EMLH_LUMO) of the mixed host R Host of the red emission layer REML can be higher than the LUMO energy level (RD_LUMO) of the red dopant RD (EMLH_LUMO>RD_LUMO).

The triplet energy level (EBL_T1) of the electron blocking layer EBL can be 0.1 eV to 0.7 eV greater than the triplet energy level (PH1_T1, PH2_T1) of each of the first and second p-type hosts. Thereby, triplet energy transfer from the red emission layer to the electron blocking layer is difficult, and excitons can be confined into the emission layer.

The second p-type host PH2 with high hole mobility can have a LUMO energy level difference (PH2_LUMO-PH1_LUMO) greater than a HOMO energy level difference (PH2_HOMO-PH1_HOMO) from the first p-type host PH1, and thus the energy band gap (PH2_Eg) of the second p-type host PH2 can be greater than the energy band gap (PH1_Eg) of the first p-type host.

The energy band gap can decrease in the order of the n-type host NH, the second p-type host PH2, the first p-type host PH1, and the red dopant RD (NH_Eg>PH2_Eg>PH1_Eg>RD_Eg).

Below is a description of specific properties of the first and second p-type hosts and the n-type host used in experiments.

The HOMO energy levels, LUMO energy levels, triplet energy levels, and energy band gaps of the first and second p-type hosts and the n-type host used in experiments are shown in Table 1 below, and the glass transition temperature (Tg) and decomposition temperature (Td) are shown in Table 2 below.

TABLE 1

| | HOMO | LUMO | T1 | Eg |
|---|---|---|---|---|
| Material | [eV] | [eV] | [eV] | [eV] |
| EBL | −5.35 | −1.88 | 2.83 | 3.47 |
| PH1 | −5.23 | −2.42 | 2.37 | 2.81 |
| PH2 | −5.19 | −2.31 | 2.38 | 2.88 |
| NH | −6.08 | −2.93 | 2.34 | 3.15 |
| 3-Mixed | −5.22 | −2.92 | 2.37 | 2.30 |
| R Host | | | | |

Table 1 also shows properties of the material for the electron blocking layer EBL having electron and exciton blocking function, in addition to the first p-type host, the second p-type host, and the n-type host.

As such, the HOMO energy level, LUMO energy level, triplet energy level, and energy band gap of the mixed host including three materials at a ratio of 0.25:0.25:0.5 are given in Table 1.

With reference to Table 1, embodiments of the present disclosure are not limited thereto, and the HOMO energy level of the first p-type host PH1 can be greater than the HOMO energy level of the second p-type host PH2.

TABLE 2

| | Tg | Td |
|---|---|---|
| Material | [° C.] | [° C.] |
| PH1 | 131 | 449 |
| PH2 | 124 | 448 |
| NH | 107 | 450 |
| 3-Mixed | 118 | 451 |
| R Host | | |

Table 2 shows the glass transition temperature (Tg) and the decomposition temperature (Td) during deposition of each of the host materials PH1, PH2, NH that make up the emission layer, and the glass transition temperature (Tg) and the decomposition temperature (Td) during deposition of the mixed host in which the three host materials PH1, PH2, NH are premixed.

Glass transition temperature (Tg) is the temperature at which the amorphous portion in a host material transitions. A light emitting device generally operates at a temperature lower than the glass transition temperature of the material. It can be said that the higher the glass transition temperature of the material, the higher the thermal stability or reliability.

For the decomposition temperature (Td), since the mixed host is deposited by evaporation when depositing the emission layer, heat is applied above the decomposition temperature to deposit the mixed host along with the dopant on the substrate on which the electron blocking layer EBL is formed.

The glass transition temperatures of the first and second p-type hosts PH1, PH2 are higher than the glass transition temperature of the n-type host NH, but the glass transition temperature of the mixed host 3-mixed R Host is adjusted to be close to the average value of glass transition temperatures of the p-type hosts PH1, PH2 and the n-type host NH.

In contrast, the decomposition temperature (Td) of the mixed host 3-mixed R Host is greater than the decomposition temperature of each of the host materials PH1, PH2, NH because deposition is possible only by evaporation of all materials.

With reference to Table 2, the glass transition temperature (Tg) and the decomposition temperature (Td) of the first p-type host PH1 can be different from those of the second p-type host PH2. For example, the glass transition temperature (Tg) and the decomposition temperature (Td) of the first p-type host PH1 can be greater than those of the second p-type host PH2. But embodiments of the present disclosure are not limited thereto. For example, one or both of the glass transition temperature (Tg) and the decomposition temperature (Td) of the first p-type host PH1 can be the same as those of the second p-type host PH2. On the other hand, when one or more of the glass transition temperature (Tg) and the decomposition temperature (Td) of the first p-type host PH1 and the second p-type host PH2 are different, the glass transition temperature (Tg) of the first p-type host PH1 can be less than that of the second p-type host PH2, or the decomposition temperature (Td) of the first p-type host PH1 can be less than that of the second p-type host PH2. In other embodiments of the present disclosure, one of the glass transition temperature (Tg) and the decomposition temperature (Td) of the first p-type host PH1 can be less than that of the second p-type host PH2, while the other of the glass transition temperature (Tg) and the decomposition temperature (Td) of the first p-type host PH1 can greater than that of the second p-type host PH2.

Below, hole mobilities of the first and second hosts are compared using HODs (hole only devices).

A HOD is a device proposed to examine hole mobility of a specific material. For comparison of hole transport capabilities of the first p-type host and the second p-type host, device characteristics are compared using either the first p-type host or the second p-type host as a host along with a red dopant in the emission layer. To this end, layers other than the emission layer include a hole transport material. The hole transport material can include, for example NPD.

The configuration of a HOD including the first p-type host as the host is as follows.

Specifically, a first electrode AND having a layered structure of ITO/Ag/ITO is provided on a substrate.

A first hole injection layer HIL1 including a p-type dopant and a hole transport material is provided on the first electrode.

Next, a hole transport layer HTL including a hole transport material is provided on the first hole injection layer.

Next, a hole transport auxiliary layer R′ HTL including a hole transport material is provided on the hole transport layer to auxiliary adjust the optical distance.

An electron blocking layer EBL including an electron blocking material is provided on the hole transport auxiliary layer.

Next, a red emission layer REML[PH1:RD] is provided by doping the first p-type host with a red dopant.

Next, a second hole injection layer HIL2 including the same p-type dopant as in the first hole injection layer and a hole transport material is provided on the red emission layer.

Next, a second electrode CAT is formed of aluminum (Al) on the second hole injection layer, thereby completing the HOD configuration.

The configuration of a HOD including the second p-type host as the host is the same as the above configuration, with the exception that the second p-type host is used in lieu of the first p-type host when forming the red emission layer.

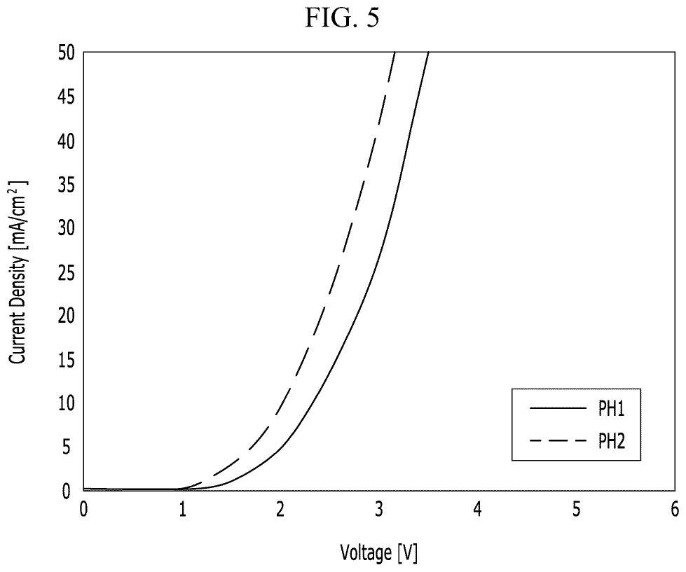

FIG. 5 is a graph comparing J-V characteristics of the first host and the second host using HODs.

As shown in FIG. 5 and Table 3 below, when comparing HODs (hole only devices) using the first p-type host and the second p-type host as respective hosts, the second p-type host is found to have a high current density at an operating voltage.

TABLE 3

| | Operating voltage | Operating voltage |
|---|---|---|
| Classification | [V] @10 mA/cm² | [V] @100 mA/cm² |
| PH1 | 2.3 | 4.2 |
| PH2 | 2.0 | 3.8 |

Referring to FIG. 5, when the hole mobility of the first p-type host is set to 1.00 at an operating voltage of 3 V, the hole mobility of the second p-type host is found to be about 1.56. But embodiments of the present disclosure are not limited thereto.

Each hole mobility of certain material layers can be determined under a same E-field through a hole only device (HOD) including an intermediate layer between opposing electrodes, by replacing the intermediate layer with a certain material layer. In a context of the hole only device (HOD), a hole mobility of the red emission layer REML having the first p-type host PH1, the second p-type host PH2, the n-type host NH, and the dopant RD can be about 4.44E-08 cm²/V·s, and the electron blocking layer EBL can have a hole mobility of 2.82E-07 cm²/V·s. Each electron mobility of certain material layers can be determined under a same E-field through an electron only device (EOD) including an intermediate layer between opposing electrodes, by replacing the intermediate layer with a certain material layer. In a context of an electron only device (EOD) as a comparison, an electron mobility of the red emission layer REML can be about 1.91E-06 cm²/V·s, and the hole blocking layer HBL can have an electron mobility of 1.49E-07 cm²/V·s. In the experiments, the E-filed of the HOD device and the EOD device is 500V/μm. There can be variance of the charge mobility (hole mobility or electron mobility) based on a structure of the HOD device or the EOD device, and use of different equipment.

The red light emitting device operates at about 2 V to 4 V, and when the first and second p-type hosts PH1, PH2 operate together, the hole mobility of the second p-type host PH2 is always greater than the hole mobility of the first p-type host PH1 in the operating voltage range of the red light emitting device.

Below is a description of device characteristics depending on the ratio of host materials in the light emitting device according to an embodiment of the present disclosure. But embodiments of the present disclosure are not limited thereto.

In the experiment, a red light emitting device with the device configuration of FIG. 1 is used, with the exception that a hole transport auxiliary layer R′ HTL is further formed between the hole transport layer HTL 120 and the electron blocking layer EBL 130 to adjust the optical distance.

Referring to FIG. 1, the light emitting device of the first experimental example EX1 has the following configuration.

A first electrode AND 110 having a layered structure of ITO/Ag/ITO is provided on a substrate.

A first common layer CML1 including a p-type dopant and a hole transport material is provided on the first electrode.

Next, a hole transport layer HTL 120 including a hole transport material is provided on the first common layer CML1.

Next, a hole transport auxiliary layer R′ HTL including a hole transport material is provided on the hole transport layer HTL 120 to auxiliary adjust the optical distance.

Next, an electron blocking layer EBL 130 including an electron blocking material is provided on the hole transport auxiliary layer R′ HTL.

Next, a red emission layer REML[PH1:NH:RD] 150 is provided by doping a mixed host of a first p-type host and an n-type host with a red dopant.

Next, a hole blocking layer HBL 160 including a hole blocking material is provided on the red emission layer 150.

Next, an electron transport layer ETL 170 is provided on the hole blocking layer HBL.

Next, an n^{th} common layer CMLn including an electron injection material is provided on the electron transport layer ETL 170.

Next, a second electrode CAT 200 is formed of a semi-transparent metal, for example an AgMg alloy on the n^{th} common layer CMLn, thereby completing the configuration of the light emitting device according to the first experimental example EX1.

In the second experimental example EX2, when forming the red emission layer 150, a second p-type host is used as the p-type host, in lieu of the first p-type host, and thus the red emission layer REML is composed of PH2, NH, and RD.

In the third to fifth experimental examples, the first and second p-type hosts and the n-type host are used together as in the embodiment of the present disclosure, with the exception that only the red emission layer configuration is different from that of the first experimental example EX1. As shown in Tables 4 and 5 below, in the third to fifth experimental examples EX3, EX4, EX5, the n-type host NH is commonly used in an amount 0.5 times the total amount of the hosts, and the first p-type host and the second p-type host are used in different amounts. In the third experimental example EX3, the amount ratio of the first p-type host to the second p-type host is 0.17:0.33. In the fourth experimental example EX4, the amount ratio of the first p-type host to the second p-type host is 0.25:0.25. In the fifth experimental example EX5, the amount ratio of the first p-type host to the second p-type host is 0.33:0.17.

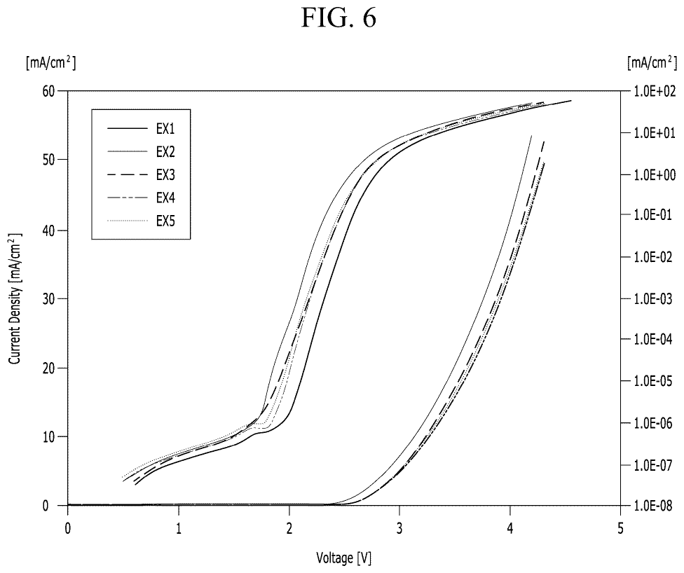

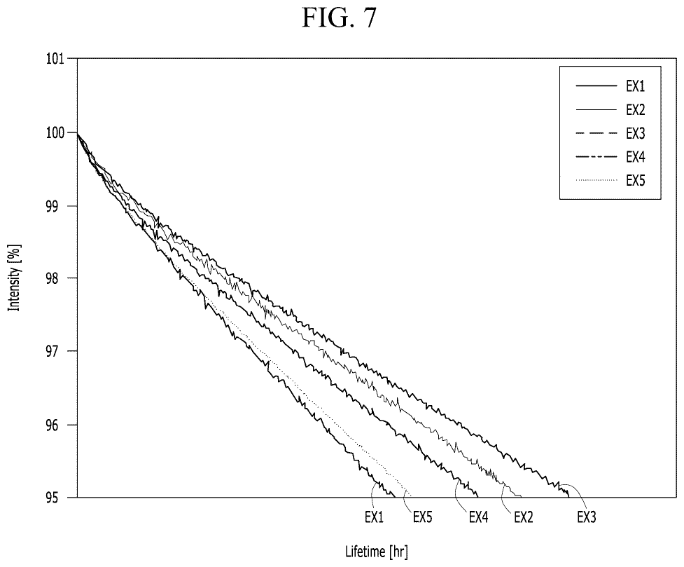

FIG. 6 is a graph showing J-V characteristics of the first to fifth experimental examples. FIG. 7 is a graph showing lifespan of the first to fifth experimental examples.

TABLE 4

| | | | | Device characteristics | | | |
|---|---|---|---|---|---|---|---|
| | Host amount ratio | | | ΔThreshold | ΔOperating | Efficiency | Lifespan |
| Classification | PH1 | PH2 | NH | voltage [V] | voltage [V] | (%) | (%) |
| EX1 | 0.50 | 0.00 | 0.50 | 0.00 | 0.0 | 100 | 100 |
| EX2 | 0.00 | 0.50 | 0.50 | −0.12 | −0.2 | 93 | 135 |
| EX3 | 0.17 | 0.33 | 0.50 | −0.11 | −0.2 | 100 | 150 |
| EX4 | 0.25 | 0.25 | 0.50 | −0.09 | −0.1 | 105 | 120 |
| EX5 | 0.33 | 0.17 | 0.50 | −0.03 | +0.1 | 104 | 105 |

Based on the first experimental example EX1 using the first p-type host among the two p-type hosts PH1, PH2, the second to fifth experimental examples EX2, EX3, EX4, EX5 are compared in terms of the threshold voltage change (Δthreshold voltage), operating voltage change (Δoperating voltage), efficiency, and lifespan of the light emitting device.

In the experiment according to Table 4, the threshold voltage change (Δthreshold voltage), operating voltage change (Δoperating voltage), and efficiency were measured in an environment of a luminance of the light emitting device of 600 nit and 25° C., and the lifespan was measured in an accelerated environment of a luminance of the light emitting device of 600 nit and 35° C. The lifespan was determined by measuring the time until the luminance reached 95% of initial luminance, and is compared with the lifespan of the first experimental example EX1.

Compared to the first experimental example EX1 including the first p-type host PH1 alone with a low HOMO energy level as the p-type host, the second experimental example EX2 including the second p-type host PH2 alone with high hole mobility reduced the turn-on threshold voltage of the light emitting device and improved the lifespan, but luminous efficacy thereof was lower than that of the first experimental example EX1.

Meanwhile, unlike the first and second experimental examples EX1, EX2, the third to fifth experimental examples EX3, EX4, EX5 including both the first and second p-type hosts PH1, PH2 exhibited equivalent or improved efficiency and further improved lifespan compared to the first experimental example EX1. This means that the third to fifth experimental examples EX3, EX4, EX5 including both the first and second p-type hosts PH1, PH2 can achieve high efficiency and long lifespan compared to the first and second experimental examples EX1, EX2 including the single p-type host material.

With reference to Table 4, the host amount ratios of the first p-type host PH1, the second p-type host PH2 and the n-type host NH can vary. For example, the host amount ratio of the first p-type host PH1 can be different from that of the second p-type host PH2, whereby the host amount ratio of the first p-type host PH1 can be less than, equal to or greater than that of that of the second p-type host PH2. In various embodiments of the present disclosure, the host amount ratio of the first p-type host PH1 can be the same or different from that of the n-type host NH, and can vary from 0.00 to 0.50, where 0.50 means that the host amount ratio of the first p-type host PH1 is equal to that of the n-type host NH. Similarly, the host amount ratio of the second p-type host PH2 can be the same or different from that of the n-type host NH, and can vary from 0.00 to 0.50, where 0.50 means that the host amount ratio of the second p-type host PH2 is equal to that of the n-type host NH. In various embodiments of the present disclosure, a combination of the host amount ratios of the first p-type host PH1 and the second p-type host PH2 can be the same or different from that of the n-type host NH. For example, the combination of the host amount ratios of the first p-type host PH1 and the second p-type host PH2 can be 0.50 or higher, but embodiments of the present disclosure are not limited thereto. For example, the combination of the host amount ratios of the first p-type host PH1 and the second p-type host PH2 can be not greater than that of the n-type host NH.

In FIG. 6, the graphs of the first to fifth experimental examples EX1-EX5 with the S curve on the left are dependent on the exponential current density on the right vertical axis, and the graphs of the first to fifth experimental examples EX1-EX5 on the right are dependent on the current density on the left vertical axis. In FIG. 6, the operating voltage change (ΔV) can be observed in the graphs of the first to fifth experimental examples EX1-EX5 on the left, and at the time point when the curve occurs in the graphs of the first to fifth experimental examples EX1-EX5 on the right, the voltage value on the horizontal axis corresponds to the threshold voltage (ΔVth) of the light emitting device.

Referring to FIG. 6, the threshold voltage value of the light emitting device was decreased in the second to fifth experimental examples EX2, EX3, EX4, EX5 compared to the first experimental example EX1.

Referring to FIG. 7, the lifespan was improved in the second to fifth experimental examples EX2, EX3, EX4, EX5 compared to the first experimental example EX1.

Based on the results of Table 4, the threshold voltage change (ΔVth) indicates comparison of the threshold voltage required upon turning-on of the light emitting device with the threshold voltage of the first experimental example EX1, and has a different meaning from the capacitance threshold voltage described above. Briefly, a small threshold voltage change (ΔVth) means that the device has the required voltage at turn-on, and the smaller the value, the better the FOS (front of screen test) characteristics of the device.

Table 5 below shows the HOMO energy level, LUMO energy level, triplet level, and energy band gap of the mixed host including three materials at different ratios.

TABLE 5

| PH1:PH2:NH(3-mixed | | HOMO | LUMO | T1 | Eg |
|---|---|---|---|---|---|
| R Host) | | [eV] | [eV] | [eV] | [eV] |
| EX3 | 0.17:0.33:0.5 | −5.20 | −2.91 | 2.36 | 2.29 |
| EX4 | 0.25.0.25:0.5 | −5.22 | −2.92 | 2.37 | 2.30 |
| EX5 | 0.33:0.17:0.5 | −5.23 | −2.92 | 2.37 | 2.31 |

Here, the LUMO energy level of the mixed host 3-mixed R Host is commonly close to the LUMO energy level of the n-type host NH in the experimental examples EX1, EX2, EX3.

Since the HOMO energy level of the mixed host 3-mixed R Host depends on hole transport characteristics, it is close to the HOMO energy level of the p-type host. In the embodiment of the present disclosure, two p-type hosts are used, and in the third experimental example EX3, the HOMO energy level of the mixed host tends to be close to the HOMO energy level of the second p-type host PH2 in a relatively high amount, and when the amount ratio of the first and second p-type hosts PH1, PH2 is 1:1 or more as in the fourth and fifth experimental examples EX4, EX5, the HOMO energy level of the mixed host tends to be close to the HOMO energy level of the first p-type host PH1 in a lower amount. When the first and second p-type hosts PH1, PH2 are included, the HOMO energy level of the mixed host is the closest to the HOMO energy of the first p-type host PH1.

As shown in Table 5, in the third to fifth experimental examples EX3, EX4, EX5, the difference between the LUMO energy level of the mixed host of the first emission layer and the HOMO energy level of the mixed host of the first emission layer is 2.29 eV to 2.31 eV, which is smaller than the energy band gap of each host. But embodiments of the present disclosure are not limited thereto.

Below is a description of changes in device characteristics and capacitance characteristics depending on material changes when using various hosts in addition to the first to fifth experimental examples.

TABLE 6

| | | | | | | | Capacitance | |
|---|---|---|---|---|---|---|---|---|
| | | | Device characteristics | | | | characteristics | |
| | Host amount ratio | | ΔThreshold | ΔOperating | Efficiency | Lifespan | Vth@ | Max |
| Classification | PH | NH | voltage [V] | voltage [V] | (%) | (%) | Cap | Cap[F] |
| EX1[PH1:NH] | 0.50 | 0.50 | 0.00 | 0.0 | 100 | 100 | 1.22 | 2.49E−09 |
| EX2[PH2:NH] | 0.50 | 0.50 | −0.12 | −0.2 | 93 | 135 | 1.00 | 2.48E−09 |
| EX3[PH1:PH2:NH] | 0.17:0.33 | 0.50 | −0.11 | −0.2 | 100 | 150 | 1.12 | 2.48E−09 |
| EX4[PH1:PH2:NH] | 0.25:0.25 | 0.50 | −0.09 | −0.1 | 105 | 120 | 1.19 | 2.51E−09 |
| EX5[PH1:PH2:NH] | 0.33:0.17 | 0.50 | −0.03 | +0.1 | 104 | 105 | 1.19 | 2.52E−09 |
| EX6[PH1:NH:NHA] | 0.5 | 0.25:0.25 | 0.00 | 0.0 | 100 | 75 | 1.11 | 2.45E−09 |
| EX7[PH2:NH:NHA] | 0.5 | 0.25:0.25 | −0.8 | −0.1 | 94 | 105 | 0.96 | 2.49E−09 |
| EX8[PH1:PH3:NH] | 0.25:0.25 | 0.5 | −0.05 | −0.1 | 99 | 110 | 1.13 | 2.51E−09 |
| EX9[PH2:PH3:NH] | 0.25:0.25 | 0.5 | −0.03 | 0.0 | 101 | 115 | 1.15 | 2.49E−09 |

In the experiment of Table 6, the first to ninth experimental examples EX1-EX9 have the device configuration described with regard to Table 5, and the first to fifth experimental examples EX1-EX5 have the HOMO energy level, LUMO energy level, energy band gap, and mobility characteristics of the first p-type host PH1, the second p-type host PH2, and the n-type host NH described in Tables 1 to 3.

The hosts of the emission layer in the sixth experimental example EX6 are configured using the first p-type host as a p-type host, and, as n-type hosts, the above-mentioned n-type host NH and an n-type host NHA having a lower LUMO energy level than the n-type host NH and low electron mobility.

The hosts of the emission layer in the seventh experimental example EX7 are configured using the second p-type host as a p-type host, and, as n-type hosts, the above-mentioned n-type host NH and an n-type host NHA having a lower LUMO energy level than the n-type host NH and low electron mobility.

The hosts of the emission layer in the eighth experimental example EX8 are configured using, as p-type hosts, the first p-type host and a third p-type host PH3 having a higher HOMO energy level than each of the first and second p-type hosts and low hole mobility, and the above-mentioned n-type host NH.

The hosts of the emission layer in the ninth experimental example EX9 are configured using, as p-type hosts, the second p-type host and a third p-type host PH3 having a higher HOMO energy level than each of the first and second p-type hosts and low hole mobility, and the above-mentioned n-type host NH.

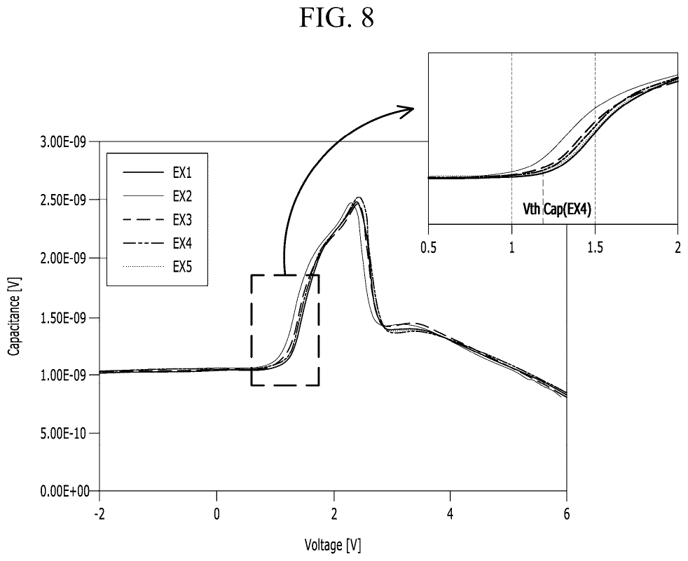

FIG. 8 is a graph showing C-V characteristics of the first to fifth experimental examples.

Capacitance threshold voltage (Vth@Cap) refers to a reference voltage at which capacitance changes rapidly. In a C-V graph with voltage on the horizontal axis and capacitance on the vertical axis, the voltage value at the point where the curve occurs is called the capacitance threshold voltage.

Referring to FIG. 8 and Table 6, the capacitance threshold voltage was the smallest in the second experimental example EX2, and was increased in all of the first experimental example EX1 and the third to fifth experimental examples EX3-EX5.

In FIG. 8, the threshold voltage of the fourth experimental example EX4 is additionally represented.

This indicates that there is no change in the capacitance of the light emitting device at a voltage value equal to or less than the threshold voltage. When the capacitance threshold voltage is increased in all of the first experimental example EX1 and the third to fifth experimental examples EX3-EX5, device reliability is improved at various voltages.

Meanwhile, the maximum values of capacitance (Max Cap) have similar levels, with a difference of up to 0.03E-09 in the first to fifth experimental examples EX1-EX5.

In the sixth experimental example EX6 using the single first p-type host PH1 and NH: NHA as the n-type hosts, lifespan characteristics were very low, showing the limit of the light emitting device.

In the seventh experimental example EX7 using the single second p-type host PH2 and NH: NHA as the n-type hosts, lifespan characteristics were improved, but luminous efficacy tended to be lowered.

In the eighth experimental Example EX8 and the ninth experimental example EX9 using either the first or second p-type host along with an additional p-type host, rather than using both the first and second p-type hosts as in the third to fifth experimental examples EX3-EX5, luminous efficacy and lifespan were equivalent to or greater than those of the first experimental example EX1 using the single p-type host.

This means that, in the red light emitting devices of the first and second experimental examples EX1, EX2 and the sixth to ninth experimental examples EX6-EX9, the use of a plurality of different p-type hosts among the p-type host and the n-type host is more effective than the use of a plurality of different n-type hosts.

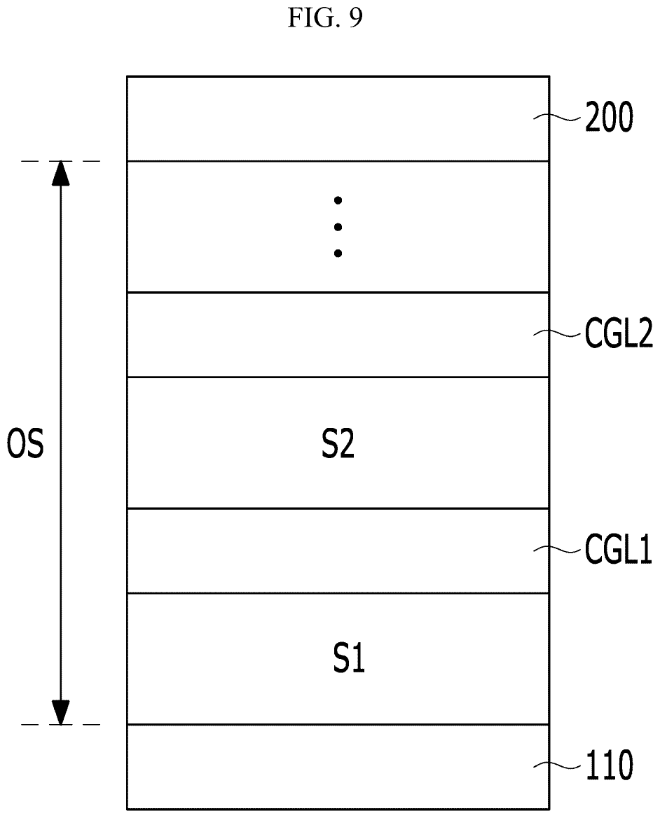

FIG. 9 is a cross-sectional view showing a light emitting device according to an embodiment of the present disclosure.

As shown in FIG. 9, the light emitting device according to an embodiment of the present disclosure includes an intermediate layer structure OS including at least two stacks S1, S2, . . . Sn configured to emit light of the same color between the first electrode 110 and the second electrode 200. The stacks S1, S2, to Sn can be divided by charge generation layers CGL1, CGL2, . . . CGLn.

Each of the stacks S1, S2, . . . can have the structure of a light emitting unit EAUN including the hole transport layer HTL, the electron blocking layer EBL, the emission layer 150, the hole blocking layer HBL, and the electron transport layer ETL described above in FIG. 1. In some cases, the hole transport layer HTL can further include a hole transport auxiliary layer thereunder or thereon.

The emission layer of each stack includes a first p-type host PH1, a second p-type host PH2, and an n-type host NH, having different properties, and a dopant D.

The p-type hosts differ in that the HOMO energy level (PH1_HOMO) of the first p-type host PH1 is lower than the HOMO energy level (PH2_HOMO) of the second p-type host PH2 (PH1_HOMO<PH2_HOMO) and the hole mobility of the second p-type host is greater than the hole mobility of the first p-type host.

When providing multiple stacks, luminous efficacy of the emission layer can be further improved, and device stability can be improved by increasing capacitance threshold voltage, in addition to a decrease in the threshold voltage of the light emitting device, an improvement in luminous efficacy, and a long lifespan effect described in the third to fifth experimental examples EX3, EX4, EX5.

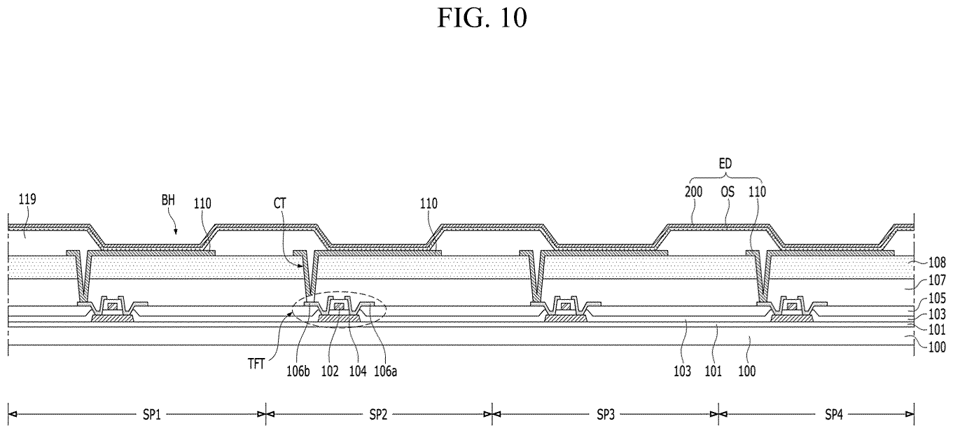

FIG. 10 is a cross-sectional view showing a light emitting display device (or a display device) according to an embodiment of the present disclosure.

As shown in FIG. 10, the light emitting display device according to an embodiment of the present invention can be configured as a display device or apparatus, such that the light emitting device described above is applied to at least one of sub-pixels SP1, SP2, SP3, SP4. All the components of the light emitting display device according to all embodiments are operationally coupled and configured.

As shown in FIG. 10, the light emitting display device according to an embodiment of the present disclosure can include a substrate 100 having a plurality of sub-pixels, a light emitting device ED commonly provided on the substrate 100, and a thin film transistor TFT provided in each of the sub-pixels and connected to the first electrode 110 of the light emitting device ED.

The thin film transistor TFT includes, for example, a gate electrode 102, a semiconductor layer 104, and a source electrode 106a and a drain electrode 106b connected to opposite sides of the semiconductor layer 104. Additionally, a channel passivation layer can be further provided on the semiconductor layer 104 in which the channel is located, in order to prevent direct connection between the source/drain electrodes 106a, 106b and the semiconductor layer 104. A buffer layer 101 can be provided on the substrate 100, and the thin film transistor TFT can be disposed on the buffer layer 101.

A gate insulating film 103 is provided between the gate electrode 102 and the semiconductor layer 104.

The semiconductor layer 104 can be formed of, for example, any one or a combination of two or more selected from among an oxide semiconductor, amorphous silicon, and polycrystalline silicon. For example, when the semiconductor layer 104 is an oxide semiconductor, the heating temperature required to form a thin film transistor can be lowered, and thus the substrate 100 has a high degree of freedom in use, whereby application to a flexible display device can become advantageous.

The gate electrode 102 can be provided on the gate insulating film 103, and an interlayer insulating film 105 can be further provided between the gate electrode 102 and the source electrode 106a/drain electrode 106b.

Moreover, the drain electrode 106b of the thin film transistor TFT can be connected to the first electrode 110 in the region of a contact hole CT provided in first and second passivation films 107, 108.

The first passivation film 107 is provided primarily to protect the thin film transistor TFT, and color filters 109R, 109G, 109B can be provided on the first passivation film 107.

The second passivation film 108 is provided on the first passivation film 107 including the color filters 109R, 109G, 109B.

When a plurality of sub-pixels includes a red sub-pixel, a green sub-pixel, a blue sub-pixel, and a white sub-pixel W_SP, the light emitting device ED described in FIG. 1 or 9 can be applied to at least the red sub-pixel. In some cases, the emission layer in each sub-pixel can be patterned separately. Some of the sub-pixels with different emission colors can include a hole transport auxiliary layer and others may not include a hole transport auxiliary layer. In the sub-pixels with different emission colors, the hole transport auxiliary layer is additionally provided to compensate for the optical distance. For example, the hole transport auxiliary layer can be thicker in a red sub-pixel than in a green sub-pixel or a blue sub-pixel.

The second passivation film 108 is formed under the first electrode 110. The first electrode 110 is formed on the surface of the second passivation film 108 excluding the contact hole CT and is connected to either the drain electrode 106b or the source electrode 106a of the thin film transistor TFT, receiving an electrical signal by the thin film transistor TFT.

Here, a structure including the substrate 100, the thin film transistor TFT, and the first and second passivation films 107, 108 can be referred to as a thin film transistor array substrate 100.

The light emitting device ED is formed on the thin film transistor array substrate 100 including a bank 119 defining a light emitting portion BH. The light emitting device ED includes a reflective first electrode 110, a semi-transparent second electrode 200 facing the same, and the intermediate layer structure OS described in FIG. 1 or 9 between the first electrode 110 and the second electrode 200. For example, when a red sub-pixel is provided with the light emitting device ED of FIG. 1 or 9, the remaining sub-pixels also include a first common layer CML1, a hole transport layer HTL, an electron blocking layer EBL, a hole blocking layer HBL, an electron transport layer ETL, an n^{th} common layer CML2, or a charge generation layer CGL, which can be continuously formed. The energy band gap can vary depending on the dopant provided for each emission layer, and the host and the light emitting dopant can be differently used.

Therefore, when the red emission layer of the red sub-pixel uses two p-type hosts and one n-type host, a single p-type host or a single n-type host, or either or both of a plurality of p-type hosts and a plurality of n-type hosts can be used in the emission layers of different colors.

In the hosts used for the emission layers of different colors, the energy band gap of the dopant of emission color can be different from that of the red dopant, so at least one of red emission layers can be differently set for optimal emission.

The first electrode 110 can be provided dividedly for each sub-pixel, and the remaining layers except for the first electrode 110 of the light emitting device ED can be provided integrally throughout the active area without separate division for each sub-pixel.

Either the first electrode 110 or the second electrode 200 can be connected to the thin film transistor TFT.

A capping layer can be provided on the second electrode 200 to improve light emission efficiency and protect the light emitting device ED.

An encapsulation layer or an encapsulation substrate can be further provided on the second electrode 200 to protect the light emitting device ED.

Although the illustrated example is shown considering top emission, the embodiment of the present disclosure is not limited thereto.

The light emitting device according to an embodiment of the present disclosure is configured such that the emission layer includes, as p-type hosts that control hole transport, a first p-type host with a low HOMO energy level and a second p-type host with high hole mobility, and an n-type host with high electron mobility.

The first p-type host with a low HOMO energy level can maintain energy balance with the electron blocking layer and can increase charge trapping efficiency in the emission layer, thus maintaining or increasing capacitance threshold voltage of the emission layer in the light emitting device.

The first p-type host can prevent excitons or electrons from leaking into the electron blocking layer through charge trapping, and the second p-type host having high mobility can optimize the mobility balance with the n-type host, thus enhancing long lifespan characteristics by preventing interfacial stress between the electron blocking layer and the emission layer.

In addition, there is an advantage in that operating voltage can be reduced by enhancing hole transport characteristics due to use of both the first and second p-type hosts.

The light emitting device according to the present disclosure and the light emitting display device including the same can improve luminous efficacy by changing the internal material of the emission layer, and also can reduce operating voltage and can lower power consumption, thus reducing environmental pollution and sustaining long lifespan characteristics, thereby realizing ESG (environment/social/governance) characteristics.

A light emitting device according to one embodiment of the present disclosure can comprise a first electrode and a second electrode facing each other and an electron blocking layer, a first emission layer, and an electron transport layer between the first electrode and the second electrode. The first emission layer can comprise a first p-type host, a second p-type host, an n-type host, and a dopant, a HOMO energy level of the first p-type host can be lower than a HOMO energy level of the second p-type host. A hole mobility of the second p-type host can be greater than a hole mobility of the first p-type host.

In a light emitting device according to one embodiment of the present disclosure, a HOMO energy level of a mixed host of the first emission layer can be close to the HOMO energy level of the first p-type host, and a LUMO energy level of the mixed host of the first emission layer can be closest to a LUMO energy level of the n-type host among the first p-type host, the second p-type host, and the n-type host.

In a light emitting device according to one embodiment of the present disclosure, a difference between the LUMO energy level of the mixed host of the first emission layer and the HOMO energy level of the mixed host of the first emission layer can be 2.29 eV to 2.31 eV. But embodiments of the present disclosure are not limited thereto.

In a light emitting device according to one embodiment of the present disclosure, the dopant can be a red dopant, the HOMO energy level of the mixed host of the first emission layer can lower than a HOMO energy level of the dopant, and the LUMO energy level of the mixed host of the first emission layer can be higher than a LUMO energy level of the dopant.

In a light emitting device according to one embodiment of the present disclosure, an absolute value of a LUMO energy level of the first p-type host can be greater than a triplet energy level of the first p-type host, and an absolute value of a LUMO energy level of the second p-type host can be less than a triplet energy level of the second p-type host.

In a light emitting device according to one embodiment of the present disclosure, a triplet energy level of the electron blocking layer can be 0.1 eV to 0.7 eV greater than triplet energy of each of the first p-type host and the second p-type host. But embodiments of the present disclosure are not limited thereto.

In a light emitting device according to one embodiment of the present disclosure, an energy band gap of the second p-type host can be greater than an energy band gap of the first p-type host.

In a light emitting device according to one embodiment of the present disclosure, an energy band gap can decrease in an order of the n-type host, the second p-type host, the first p-type host, and the dopant.

In a light emitting device according to one embodiment of the present disclosure, the dopant can have an emission peak at a wavelength of 600 nm to 650 nm. But embodiments of the present disclosure are not limited thereto.

A light emitting device according to one embodiment of the present disclosure can further comprise a hole blocking layer between the first emission layer and the electron transport layer.

In a light emitting device according to one embodiment of the present disclosure, a difference between a LUMO energy level of the first emission layer and a LUMO energy level of the electron blocking layer can be greater than a difference between a HOMO energy level of the first emission layer and a HOMO energy level of the hole blocking layer.

In a light emitting device according to one embodiment of the present disclosure, a total amount of the first p-type host and the second p-type host can be substantially equal to an amount of the n-type host.

In a light emitting device according to one embodiment of the present disclosure, at least one stack can be provided to at least one of between the first electrode and the electron blocking layer or between the electron transport layer and the second electrode. At least one stack can comprise a first common layer, a second emission layer, and a second common layer. The second emission layer can emit light of a same color as emitted light from the first emission layer.

In a light emitting device according to one embodiment of the present disclosure, the second emission layer can comprise the first p-type host, the second p-type host, and a red dopant.

A light emitting display device according to one embodiment of the present disclosure can comprise a substrate comprising a plurality of sub-pixels, a thin film transistor provided in each of the plurality of sub-pixels and a light emitting device connected to the thin film transistor in at least one of the plurality of sub-pixels. Tight emitting device can comprise an electron blocking layer, a first emission layer, and an electron transport layer between a first electrode and a second electrode. The first emission layer can comprise a first p-type host, a second p-type host, an n-type host, and a dopant, a HOMO energy level of the first p-type host can be lower than a HOMO energy level of the second p-type host, and a hole mobility of the second p-type host can be greater than a hole mobility of the first p-type host.

As is apparent from the above description, a light emitting device according to the present disclosure and a light emitting display device including the same have the following effects.

As is apparent from the above description, a light emitting device according to an embodiment of the present disclosure is configured such that an emission layer includes, as p-type hosts that control hole transport, a first p-type host with a low HOMO energy level and a second p-type host with high hole mobility, and an n-type host with high electron mobility.

The first p-type host with a low HOMO energy level can maintain energy balance with an electron blocking layer and can increase charge trapping efficiency in the emission layer, thereby maintaining or increasing capacitance threshold voltage of the emission layer in the light emitting device.

The first p-type host can prevent excitons or electrons from leaking into the electron blocking layer through charge trapping, and the second p-type host having high mobility can optimize the mobility balance with the n-type host, thus preventing interfacial stress between the electron blocking layer and the emission layer, thereby enhancing long lifespan characteristics.

In addition, there is an advantage in that operating voltage can be reduced by enhancing hole transport characteristics by providing both the first and second p-type hosts.

The light emitting device according to the present disclosure and the light emitting display device including the same can improve luminous efficacy by changing the internal material of the emission layer, and also can reduce operating voltage and can lower power consumption, thereby reducing environmental pollution and sustaining long lifespan characteristics, thus realizing ESG (environment/social/governance) characteristics.

While the embodiments of the present disclosure have been described with reference to the accompanying drawings, the present disclosure is not limited to the embodiments and can be embodied in various different forms, and those skilled in the art will appreciate that the present disclosure can be embodied in specific forms other than those set forth herein without departing from the technical idea and essential characteristics of the present disclosure. The disclosed embodiments are therefore to be construed in all aspects as illustrative and not restrictive.

What is claimed is:

1. A light emitting device, comprising:
a first electrode and a second electrode facing each other; and
an electron blocking layer, a first emission layer, and an electron transport layer between the first electrode and the second electrode,
wherein the first emission layer comprises a first p-type host, a second p-type host, an n-type host, and a dopant,
wherein a Highest Occupied Molecular Orbital (HOMO) energy level of the first p-type host is lower than a HOMO energy level of the second p-type host, and
wherein a hole mobility of the second p-type host is greater than a hole mobility of the first p-type host.

2. The light emitting device according to claim 1, wherein:
a HOMO energy level of a mixed host of the first emission layer is closer to the HOMO energy level of the first p-type host than that of the second p-type host, and
a Lowest Unoccupied Molecular Orbital (LUMO) energy level of the mixed host of the first emission layer is closest to a LUMO energy level of the n-type host among the first p-type host, the second p-type host, and the n-type host.

3. The light emitting device according to claim 2, wherein a difference between the LUMO energy level of the mixed host of the first emission layer and the HOMO energy level of the mixed host of the first emission layer is approximately 2.29 eV to 2.31 eV.

4. The light emitting device according to claim 2, wherein:
the dopant is a red dopant,
the HOMO energy level of the mixed host of the first emission layer is lower than a HOMO energy level of the dopant, and
the LUMO energy level of the mixed host of the first emission layer is higher than a LUMO energy level of the dopant.

5. The light emitting device according to claim 1, wherein:
an absolute value of a Lowest Unoccupied Molecular Orbital (LUMO) energy level of the first p-type host is greater than a triplet energy level of the first p-type host, and
an absolute value of a LUMO energy level of the second p-type host is less than a triplet energy level of the second p-type host.

6. The light emitting device according to claim 1, wherein a triplet energy level of the electron blocking layer is approximately 0.1 eV to 0.7 eV greater than triplet energy level of each of the first p-type host and the second p-type host.

7. The light emitting device according to claim 1, wherein an energy band gap of the second p-type host is greater than an energy band gap of the first p-type host.

8. The light emitting device according to claim 1, wherein an energy band gap decreases in an order of the n-type host, the second p-type host, the first p-type host, and the dopant.

9. The light emitting device according to claim 1, wherein the dopant has an emission peak at a wavelength of approximately 600 nm to 650 nm.

10. The light emitting device according to claim 1, further comprising a hole blocking layer between the first emission layer and the electron transport layer.

11. The light emitting device according to claim 10, wherein a difference between a Lowest Unoccupied Molecular Orbital (LUMO) energy level of the first emission layer and a LUMO energy level of the electron blocking layer is greater than a difference between a HOMO energy level of the first emission layer and a HOMO energy level of the hole blocking layer.

12. The light emitting device according to claim 1, wherein a total amount of the first p-type host and the second p-type host is substantially equal to an amount of the n-type host.

13. The light emitting device according to claim 1, wherein:
at least one stack is provided to at least one of between the first electrode and the electron blocking layer or between the electron transport layer and the second electrode,
the at least one stack comprises a first common layer, a second emission layer, and a second common layer, and
the second emission layer emits light of a same color as emitted light from the first emission layer.

14. The light emitting device according to claim 13, wherein the second emission layer comprises the first p-type host, the second p-type host, and a red dopant.

15. The light emitting device according to claim 1, wherein the first p-type host and the second p-type host are tertiary arylamine compounds, and
wherein the tertiary arylamine compound of the second p-type host differs from the tertiary arylamine compound of the first p-type host by a component of an organic substituent that binds to nitrogen.

16. The light emitting device according to claim 1, wherein the n-type host is any one of triazole, triazine, benzothiazole, carbazole, benzimidazole, and oxadiazole.

17. The light emitting device according to claim 1, wherein the host amount ratio of the first p-type host is less than or equal to the host amount ratio of the second p-type host.

18. A light emitting display device, comprising:
a substrate comprising a plurality of sub-pixels;
a thin film transistor provided in each of the plurality of sub-pixels; and
the light emitting device according to claim 1, and connected to the thin film transistor in at least one of the plurality of sub-pixels, wherein the light emitting device includes the electron blocking layer, the first emission layer, and the electron transport layer between the first electrode and the second electrode.

19. A light emitting device, comprising:
a first electrode and a second electrode facing each other; and
an electron blocking layer, a first emission layer, and an electron transport layer between the first electrode and the second electrode,
wherein the first emission layer comprises a first p-type host, a second p-type host, an n-type host, and a dopant,
wherein a Highest Occupied Molecular Orbital (HOMO) energy level of the first p-type host is different from than a HOMO energy level of the second p-type host, and
wherein at least one of the first p-type host and the second p-type host is a tertiary arylamine compound.

20. The light emitting device according to claim 19, wherein a hole mobility of the second p-type host is greater than a hole mobility of the first p-type host.
